(19) United States
(12) Patent Application Publication
(10) Pub. No.: US 2021/0269049 A1
(43) Pub. Date: Sep. 2, 2021

(54) Failure-Tolerant By-Wire Actuator Interface

(71) Applicants: Kevin M. Hallenbeck, Waterford, MI (US); Steven J. Grzebyk, Rochester Hills, MI (US); James C. Smith, Farmington Hills, MI (US)

(72) Inventors: Kevin M. Hallenbeck, Waterford, MI (US); Steven J. Grzebyk, Rochester Hills, MI (US); James C. Smith, Farmington Hills, MI (US)

(73) Assignee: DATASPEED INC., Rochester Hills, MI (US)

(21) Appl. No.: 16/806,187

(22) Filed: Mar. 2, 2020

(51) Int. Cl. B60W 50/02; H04L 27/156

(52) U.S. Cl. CPC B60W 50/0205; B60W 2050/0055; H04L 27/156

(57) ABSTRACT

A fail-safe interface for a by-wire vehicle control system merges driver commands and external commands developed by a by-wire control unit to form a failure-tolerant actuator command that never diminishes a driver command. External commands are passed through a fault detection circuit that filters out aberrant cyclical and constant command signals from the by-wire control unit, and the actuator command is determined according to the higher or maximum of the driver-generated and external commands. The interface is powered by vehicle power supply, and is electro-optically isolated from the external control unit so that if the external control unit loses power, the actuator command faithfully follows the driver command.

### TECHNICAL FIELD

This invention relates to the by-wire control of engine and brake actuators, and more particularly to a fail-safe interface for merging and prioritizing driver and externally generated by-wire commands.

### BACKGROUND OF THE INVENTION

By-wire technology is increasingly being used by vehicle manufacturers as a means of electronically controlling driver-regulated functions such as powerplant and braking controls. This replaces the traditional mechanical linkages, but also importantly, it enables an alternate or supplemental control of these functions by an external computer-based control unit. “External” in this sense, simply means a control unit separate from the on-board or OEM (original equipment manufacturer) controller that is designed to carry out driver commands. Typically, the alternate or supplemental control is safety related, as in the case of automatic braking or stability control, but it can also be an autonomous driving control designed to operate the vehicle without driver input. These alternate or supplemental controls frequently command actions that are not commanded by the driver, but it is important that due deference be given to driver commands when they are present, and also to avoid abrupt transitions between driver control and external control. At the same time, it is important to address potential failure modes of the external control unit to minimize unintended overriding of a driver-generated command. Accordingly, what is needed is an improved and failure-tolerant interface for merging and prioritizing the driver and external commands in these systems.

### SUMMARY OF THE INVENTION

The present invention is directed to an improved and failure-tolerant interface circuit for a by-wire vehicle control system in which driver commands and external commands developed by a control unit are merged to form failure-tolerant actuator commands that never diminish the driver commands. The external commands are passed through a fault detection circuit that filters out aberrant cyclical and constant command signals from the external control unit, and the actuator command is determined according to the higher or maximum of the driver-generated and external commands. The interface is powered by vehicle power supply, and is electro-optically isolated from the control unit that develops the external commands so that if the control unit loses power, the actuator command faithfully follows the driver command.

### BRIEF DESCRIPTION OF THE DRAWINGS

FIG. 1 is a block diagram of a by-wire vehicle control system, including an external computer-based control unit and a failure-tolerant by-wire interface circuit according to the present invention.

FIG. 2 is a diagram of the failure-tolerant by-wire interface circuit of FIG. 1, as applied to a brake actuator.

FIG. 3 is a diagram of the failure-tolerant by-wire interface circuit of FIG. 1, as applied to a powerplant actuator.

### DESCRIPTION OF THE PREFERRED EMBODIMENT

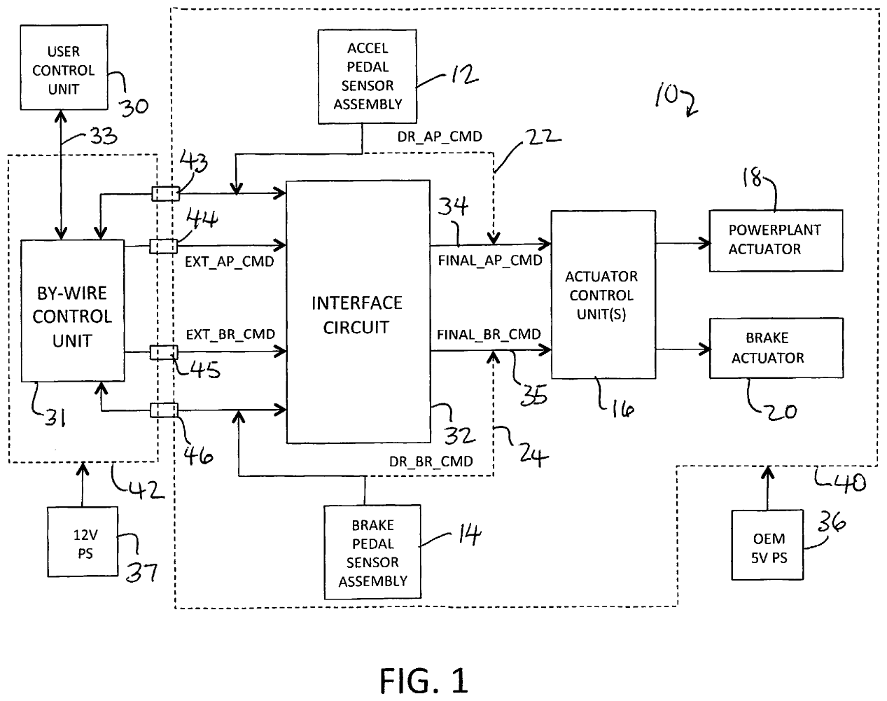

In general, the present invention is designed to enable a user control unit to seamlessly interface with an OEM vehicle by-wire control system, as generally depicted in the diagram of FIG. 1. Referring to FIG. 1, the reference numeral 10 generally designates the elements of a typical OEM by-wire powerplant and brake control system, including a driver-manipulated Accelerator Pedal and Sensor Assembly 12, a Driver-Manipulated Brake Pedal and Sensor Assembly 14, an on-board Actuator Control Unit 16, one or more Powerplant Actuators 18, and a Brake Actuator 20. The assembly 12 is responsive to accelerator pedal position, and develops a driver accelerator command (DR_AP_CMD), and similarly, the assembly 14 senses the brake pedal position as a measure of the force the driver applies to the brake pedal, and develops a corresponding driver brake command (DR_BR_CMD). These commands are ordinarily provided as inputs to the Actuator Control Unit 16, as indicated by the broken lines 22 and 24, and the Actuator Control Unit 16 energizes Powerplant Actuator 18 and Brake Actuator 20 as required to satisfy the driver commands. If the vehicle's powerplant is an internal combustion engine, for example, the Actuator Control Unit 16 determines one or more engine settings such as throttle angle, spark timing, fuel injector pulse width, and so forth for satisfying the driver accelerator command, and energizes the Powerplant Actuator 18 accordingly. Of course, the system 10 can be configured with a dedicated actuator control unit for each actuator, if desired.

Also depicted in FIG. 1 are three major elements external to the OEM by-wire system 10: a User Control Unit 30, a By-Wire Control Unit 31, and an Interface Circuit 32. When these elements are applied to the OEM system 10, the driver commands DR_AP_CMD and DR_BR_CMD are applied as inputs to the By-Wire Control Unit 31 and the Interface Circuit 32 instead of directly to the Actuator Control Unit 16. In this configuration, the User Control Unit 30 supplies vehicle guidance instructions via communication bus 33 to the By-Wire Control Unit 31, from which the By-Wire Control Unit 31 develops corresponding external by-wire accelerator and brake commands EXT_AP_CMD and EXT_BR_CMD. The Interface Circuit 32 receives and merges the external by-wire commands and the driver-generated by-wire commands to form final accelerator and brake commands FINAL_AP_CMD and FINAL_BR_CMD that are supplied to the Actuator Control Unit 16 on lines 34 and 35. And the Actuator Control Unit 16 energizes the Powerplant Actuator 18 and Brake Actuator 20 as required to satisfy the final commands.

As noted above, the Interface Circuit 32 gives due deference to the driver-generated commands by developing the final commands according to the higher or maximum of the driver-generated and external commands. This also means that if By-Wire Control Unit 31 loses power, the final commands produced by Interface Circuit 32 faithfully follow the driver commands. Using braking as an example, the Interface Circuit 32 will allow the By-Wire Control Unit 31 to cause more braking than the driver braking command, but not less; put another way, the driver will always be able to cause more braking than the By-Wire Control Unit 31 is commanding (unless both are commanding maximum braking, of course). A similar philosophy is applies to the accelerator commands, or any other actuator control.

The Interface Circuit 32 is powered by a vehicle-based power supply 36 that also supplies power to the various components of the OEM system 10, as indicated by the broken outline 40. The By-Wire Control Unit 31, on the other hand, is powered by a separate or external power supply 37, as indicated by the broken outline 42. And electro-optical isolators 43, 44, 45 and 46 electrically isolate the inputs and outputs of the By-Wire Control Unit 31. These measures electrically isolate the By-Wire Control Unit 31 from the Interface Circuit 32 and the rest of the OEM control system 10 so that electrical faults in the By-Wire Control Unit 31 or its power supply 37 do not cause faulty operation of the Interface Circuit 32 and OEM control system 10.

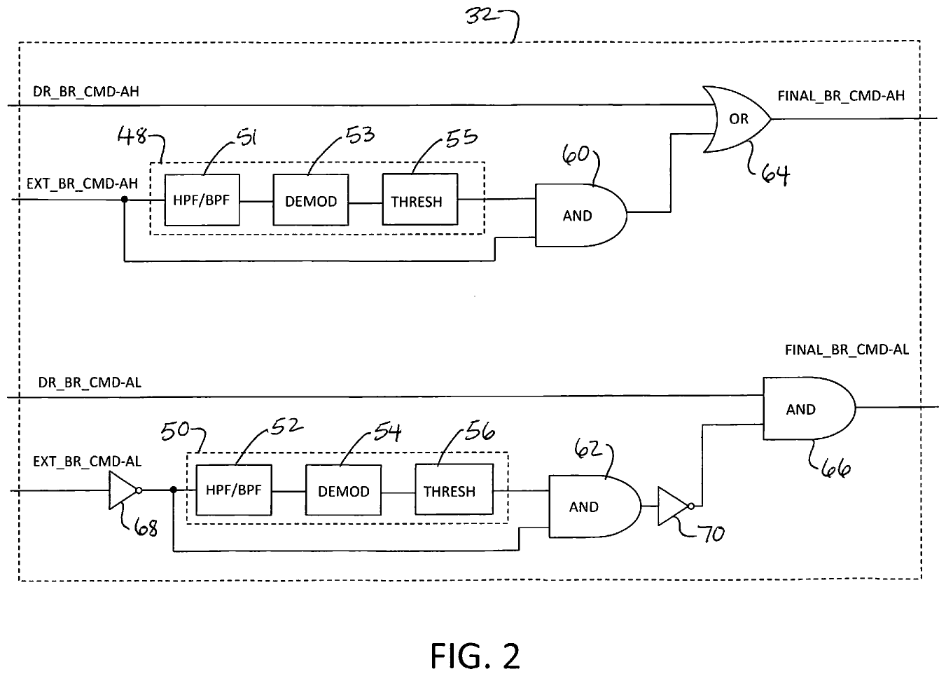

An embodiment of the Interface Circuit 32 as applied to brake pedal position is depicted in FIG. 2. In the illustrated embodiment, the driver brake command is generated in the form of a digital signal, specifically, a pulse-width-modulated (PWM) voltage having a duty cycle that nominally represents the linear span of 0% to 100% brake pedal position. In OEM vehicles, however, such a digital signal command is typically implemented for safety reasons as a pair of complementary PWM signals: one being active-high, and the other being active-low. This provides a measure of redundancy and signal integrity assurance since the signals will have the same duty cycle after accounting for the polarity difference during correct operation of the brake pedal assembly 14. The actuator control unit 16 compares the two signals, and if the signal complementarity is satisfied, activates the brake actuator 20 accordingly. This means that the By-Wire Control Unit 31 must also code its brake command as a pair of complementary digital PWM voltages. In FIG. 2, the active high (AH) and active low (AL) driver brake commands are designated as DR_BR_CMD-AH and DR_BR_CMD-AL; and the external brake commands are designated as EXT_BR_CMD-AH and EXT_BR_CMD-AL.

In general, the Interface Circuit 32 includes, for each of the complementary external brake commands, a Fault-Detection Circuit 48 or 50, an AND-gate 60 or 62 for logically combining filtered and unfiltered external commands, and a logic gate 64 or 66 for logically combining the AND-gate output with the corresponding driver brake command. In the active-high portion of the circuit, the combining logic gate 64 is an OR-gate, whereas in the active-low portion of the circuit, the combining logic gate 66 is an AND-gate. The Fault-Detection Circuits 48 and 50, in conjunction with AND-gates 60 and 62, screen the external brake commands EXT_BR_CMD-AH and EXT_BR_CMD-AL for the most common fault modes. Fault-mode commands are forced to their inactive logic level, while non-fault-mode commands are passed unaltered. The logic gates 64 and 66 form the final brake commands FINAL_BR_CMD-AH and FINAL_BR_CMD-AL as the higher the driver brake commands DR_BR_CMD-AH or DR_BR_CMD-AL and the output of the respective AND-gates 60 and 62. In other words, the final brake commands FINAL_BR_CMD-AH and FINAL_BR_CMD-AL will have a duty cycle that is the greater of the driver and screened or passed external brake commands.

The Fault-Detection Circuits 48 and 50 screen the digital external brake commands by determining if they are actively toggling high and low within a specified range or band of frequencies. In the illustrated embodiment, this functionality is implemented with the serial combination of a high-pass filter (HPF)—or alternately, a band-pass filter (BPF)—51 or 52, a demodulator (DEMOD) 53 or 54, and a threshold circuit (THRESH) 55 or 56. Their output is a logic HIGH if no fault is detected, or a logic LOW when a faulty command is detected. These faults include both constant failure modes (that is, stuck-high or stuck-low), and invalid cyclic failure modes. The logic HIGH output enables the respective AND-gate 60 or 62 to pass the unfiltered external command, whereas the logic LOW output disables/prevents the AND-gate 60 or 62 from passing the unfiltered external command. The filters 55 or 56 are designed to pass external command signals that are actively toggling within the specified range or band of frequencies, but otherwise ideally produce a zero output. The demodulators 53 and 54 can be implemented with a timing circuit that directly determines the duty cycle of the respective PWM signal, or more simply with a low-pass filter, to produce an analog voltage proportional to the duty cycle of the filter output. And the threshold circuits 55 or 56 establish an analog voltage corresponding to a minimum PWM duty cycle; if the output of the respective demodulator 53 or 54 exceeds the threshold, the threshold circuit 55 or 56 outputs a logic HIGH, but if the demodulator output is below the threshold, the threshold circuit 55 or 56 outputs a logic LOW. This, as mentioned above, is the enable/disable signal for AND-gate 60 or 62.

In the illustrated embodiment, the active-low portion of the Interface Circuit 32 includes two additional components: an input inverter 68 upstream of Fault-Detection Circuit 50 for initially converting the active-low external brake command EXT_BR_CMD-AL to an active-high signal, and a restorative inverter 70 between AND-gate 62 and OR-gate 66 for converting the filtered signal back to an active-low signal. This allows the Fault-Detection Circuit Circuits 48 and 50 to be identical, as they both operate on active-high PWM commands. Of course, the function of inverter 68 can be implemented in the By-Wire Control Unit 31 instead of the Interface Circuit 32, if desired.

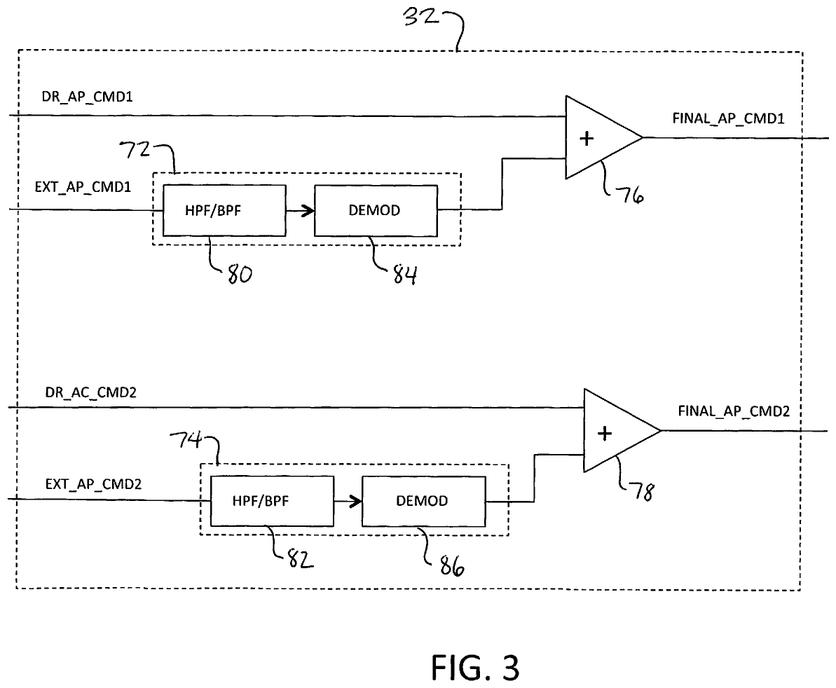

An embodiment of the Interface Circuit 32 as applied to accelerator pedal position is depicted in FIG. 3. In the illustrated embodiment, the driver accelerator command is generated as an analog signal with a voltage range that nominally represents the linear span of 0% to 100% accelerator pedal position. In OEM vehicles, however, such an analog command is typically implemented for safety reasons as a pair of complementary analog voltages, where one is a multiple of the other. For example, one signal (DRIVER_AP_CMD1) can have a range of 0.4 VDC to 4.8 VDC, and the other signal (DRIVER_AP_CMD2) can have a range of 0.2 VDC to 2.4 VDC. This provides a measure of redundancy and signal integrity assurance since the first signal will be exactly double the second signal during correct operation of the accelerator pedal assembly 12. The Actuator Control Unit 16 compares the two signals, and if the signal complementarity is satisfied, activates the Powertrain Actuator(s) 18 accordingly. The By-Wire Control Unit 31, on the other hand, codes its accelerator commands as equivalent PWM voltages; this is not only easier for a computer-based control unit, but it also retains compatibility with the fault detection filter circuits of FIG. 2. Additionally, for reasons that will become apparent below, the accelerator command output of the By-Wire Control Unit 31 is based on the amount by which the external command exceeds the driver command. In other words, the By-Wire Control Unit 31 determines a desired accelerator command, reduces it by the driver accelerator command (limited to zero, of course), and then outputs the PWM command based on the reduced value. In the diagram of FIG. 3, the complementary driver accelerator commands are designated as DR_AP_CMD1 and DR_AP_CMD2; and the complementary external accelerator commands developed by By-Wire Control Unit 31 are designated as EXT_AP_CMD1 and EXT_AP_CMD2.

In general, the Interface Circuit 32 includes, for each of the complementary external accelerator commands, a Fault-Detection Circuit 72 or 74, and a Summing Junction 76 or 78 for summing the filter output with the corresponding driver accelerator command. In effect, the Interface Circuit 32 sets the final accelerator command according to the higher of the driver command and the external command. As with the embodiment of FIG. 2, the Fault-Detection Circuit filters 72 and 74 respectively screen the external accelerator commands EXT_AP_CMD1 and EXT_AP_CMD2 for the most common fault modes. Fault-mode commands are forced to their inactive logic level, while non-fault-mode commands are passed unaltered. Thus, the Fault-Detection Circuit filters 72, 74 screen the digital external accelerator commands by determining if they are actively toggling high and low within a specified range or band of frequencies. In the illustrated embodiment, this functionality is implemented with the serial combination of a high-pass filter (HPF)—or alternately, a band-pass filter (BPF)—80 or 82, and a demodulator (DEMOD) 84 or 86 to convert it to an analog voltage. If the external accelerator command is not actively changing within the specified frequency range, the filter output will ideally be zero. This effectively forces aberrant external accelerator pedal commands, including constant (stuck-high or stuck-low), and invalid cyclic failure modes, to the inactive (low) logic level. However, if the external accelerator commands are actively toggling at a frequency that the respective filters 80 or 82 pass, they will pass through to the demodulator 84 or 86. The demodulators 84 and 86 can be implemented with a timing circuit that directly determines the duty cycle of the respective PWM signal, or more simply, with comparator followed by a low-pass filter. The comparator restores the PWM signal to toggle between 0V and 5V so that when it is low-pass filtered, the resulting analog voltage is proportional to the duty cycle of the PWM signal. These analog voltages are then summed with the respective driver accelerator commands by Summing Junctions 76 and 78 (which may be implemented with operational amplifiers, for example) to form the final accelerator commands FINAL_AP_CMD1 and FINAL_AP_CMD2.

The combination of reducing the external accelerator command by the driver command (in the By-Wire Control Unit 31), and subsequently summing the analog external and driver commands (in Summing Junctions 76 and 78) serves to set the final accelerator commands according to the higher of the external and driver accelerator commands. For example, if the driver accelerator commands correspond to 50% pedal position, but the external accelerator pedal command is 60%, the By-Wire Control Unit 31 outputs its accelerator command based on a pedal position of 60%−50%=10%, which will cause the Summing Junctions 76 and 78 of Interface Circuit 32 to increase the driver commands by amounts corresponding to 10% pedal position, and the Powertrain Actuator 18 is regulated according to the external command. On the other hand, if the external accelerator command is less than or equal to the driver command, the By-Wire Control Unit 31 outputs its actuator command based on 0% pedal position; in this case, the Summing Junctions 76 and 78 do not increase the driver accelerator command, and the Powertrain Actuator 18 is regulated according to the driver command. Of course, the subtraction function ascribed to the By-Wire Control Unit 31 could alternatively be carried out in the Interface Circuit 32, if desired.

In summary, the present invention provides an improved and fault-tolerant interface for merging and prioritizing the driver and external commands in vehicular by-wire control systems. It will be recognized that while the invention has been described in reference to the vehicle powerplant and brake controls, it is applicable to other types of actuator control as well, and that numerous modifications and variations in addition to those mentioned herein will occur to those skilled in the art. Accordingly, it will be appreciated that systems incorporating these and other modifications and variations still fall within the intended scope of the invention.

1. A by-wire control system for a vehicle, comprising:
a sensor assembly manipulated by a driver of the vehicle that produces a first electrical signal indicative of a driver command for a vehicle control parameter;
an external control unit for producing a second electrical signal indicative of an external command for said control parameter;
an actuator that regulates said control parameter in accordance with a third electrical signal indicative of a final command for said control parameter; and
an interface circuit that merges said first and second electrical signals to form said third electrical signal, including a filter circuit that blocks said second electrical signal during specified fault modes of said external control unit while otherwise passing said second electrical signal a filter circuit output, and a merging circuit for setting said third electrical signal equal to said first electrical signal when said driver command equals or exceeds said external command, and otherwise setting said third electrical signal equal to said filter circuit output.

2. The by-wire control system of claim 1, further comprising:
an electrical isolation circuit through which said second electrical signal is supplied to said interface circuit so that an electrical failure of said external control unit does not cause a failure of said interface circuit.

3. The by-wire control system of claim 1, where:
said second electrical signal is a pulse width modulated signal having a duty cycle based on said external command; and
said filter circuit includes a high-pass or band-pass filter responsive to said second electrical signal, a demodulator for demodulating an output of said filter.

4. The by-wire control system of claim 3, where:
said first electrical signal is a pulse width modulated signal having a duty cycle based on said driver command; and
said filter circuit includes an AND-gate for logically combining said second electrical signal with an output of said demodulator to form said filter circuit output.

5. The by-wire control system of claim 4, where said output of said demodulator disables said AND-gate to block said
second electrical signal during said specified fault modes of said external control unit, and otherwise enables said AND-gate to pass said second electrical signal to said filter circuit output.

6. The by-wire control system of claim 3, where:
said first electrical signal is a pulse width modulated signal having a duty cycle based on said driver command; and
said merging circuit includes a logic gate that combines said filter circuit output with said first electrical signal.

7. The by-wire control system of claim 3, where:
said first electrical circuit is an analog voltage having a magnitude based on said driver command; and
said demodulator includes a low-pass filter for converting an output of said filter into an analog voltage.

8. The by-wire control system of claim 7, where:
said merging circuit includes a summer for combining an output of said low-pass filter with said first electrical signal to form said third electrical signal.

9. The by-wire control system of claim 1, where:
said sensor assembly is an accelerator pedal sensor assembly, and said driver command is an accelerator pedal position.

10. The by-wire control system of claim 1, where:
said sensor assembly is an brake pedal sensor assembly, and said driver command is an brake pedal position.

11. The by-wire control system of claim 1, further comprising:
a first power supply for supplying power to said sensor assembly, said actuator and said interface circuit;
a second power supply for supplying power to said external control unit; and
an electrical isolation circuit through which said second electrical signal is supplied to said interface circuit so that an electrical failure of said second power supply does not cause a failure of said interface circuit.
